(19) United States
(12) Patent Application Publication
(10) Pub. No.: US 2019/0319102 A1
(43) Pub. Date: Oct. 17, 2019

(54) SEMICONDUCTOR DEVICE

(71) Applicant: SUMITOMO ELECTRC INDUSTRIES, LTD., Osaka (JP)

(72) Inventor: Takashi TSUNO, Hyogo (JP)

(21) Appl. No.: 16/349,775

(22) PCT Filed: Jun. 29, 2017
(86) PCT No.: PCT/JP2017/024054

§ 371 Date: May 14, 2019

(30) Foreign Application Priority Data
Nov. 25, 2016 (JP) 2016-229024

(51) Int. Cl. H01L 29/16; H01L 21/28; H01L 21/04; H01L 29/41; H01L 29/49; H01L 29/78; H01L 29/06; H01L 29/08; H01L 29/66

(52) U.S. Cl. CPC H01L 29/1608; H01L 21/28; H01L 21/049; H01L 29/41; H01L 29/66068; H01L 29/78; H01L 29/0657; H01L 29/0878; H01L 29/49

(57) ABSTRACT

A semiconductor device includes: a silicon carbide epitaxial layer formed on one main surface of a single-crystal silicon carbide substrate; a recessed portion and a protruding portion formed on a surface of the silicon carbide epitaxial layer; an inclined surface formed between the recessed portion and the protruding portion; a first contact area of first conductivity type formed on the inclined surface side of the bottom surface of the recessed portion; a second contact area of second conductivity type in contact with the first contact area; a drift area of first conductivity type formed on an upper surface of the protruding portion; a body area of second conductivity type formed on the inclined surface between the first contact area and the drift area; a gate insulating film that covers the inclined surface; a gate electrode; a source electrode; and a drain electrode, wherein an angle of the inclined surface with respect to the one main surface of the single-crystal silicon carbide substrate is 40° or more and 70° or less.

### TECHNICAL FIELD

The present disclosure relates to a semiconductor device.

The present application is based on and claims priority to Japanese Patent Application No. 2016-229024, filed on Nov. 25, 2016, the entire contents of which are hereby incorporated herein by reference.

### BACKGROUND ART

As semiconductor devices compatible with high withstand voltage, silicon carbide semiconductor devices are present. As such silicon carbide semiconductor device, a MOSFET (metal-oxide-semiconductor field-effect transistor) in which a channel is formed in the in-plane direction is disclosed (for example, Patent Document 1).

### PRIOR ART DOCUMENT

### [Patent Document]

[Patent Document 1] International Publication Pamphlet No. WO 2013/145023

### SUMMARY OF THE INVENTION

According to one aspect of the embodiment, a semiconductor device includes: a single-crystal silicon carbide substrate; a silicon carbide epitaxial layer formed on one main surface of the single-crystal silicon carbide substrate; a recessed portion and a protruding portion formed on a surface of the silicon carbide epitaxial layer; and an inclined surface formed between the recessed portion and the protruding portion. Also, the semiconductor device includes: a first contact area of first conductivity type formed on the inclined surface side of a bottom surface of the recessed portion; a second contact area of second conductivity type in contact with the first contact area at the bottom surface of the recessed portion; a drift area of first conductivity type formed on an upper surface of the protruding portion; and a body area of second conductivity type formed on the inclined surface between the first contact area and the drift area. Also, the semiconductor device includes: a gate insulating film that covers the inclined surface; a gate electrode formed on the gate insulating film; a source electrode formed on the first contact area and the second contact area; and a drain electrode formed on the other main surface of the single-crystal silicon carbide substrate. An angle of the inclined surface with respect to the one main surface of the single-crystal silicon carbide substrate is 40° or more and 70° or less.

### BRIEF DESCRIPTION OF THE DRAWINGS

FIG. 1 is a schematic planar view illustrating a semiconductor layer of a semiconductor device according to one aspect of the present disclosure;

FIG. 2 is a schematic cross-sectional view illustrating the semiconductor device according to one aspect of the present disclosure;

FIG. 3 is a diagram illustrating a step of a method of manufacturing the semiconductor device according to one aspect of the present disclosure (1);

FIG. 4 is a diagram illustrating a step of the method of manufacturing the semiconductor device according to one aspect of the present disclosure (2);

FIG. 5 is a diagram illustrating a step of the method of manufacturing the semiconductor device according to one aspect of the present disclosure (3);

FIG. 6 is a diagram illustrating a step of the method of manufacturing the semiconductor device according to one aspect of the present disclosure (4);

FIG. 7 is a diagram illustrating a step of the method of manufacturing the semiconductor device according to one aspect of the present disclosure (5);

FIG. 8 is a diagram illustrating a step of the method of manufacturing the semiconductor device according to one aspect of the present disclosure (6);

FIG. 9 is a diagram illustrating a step of the method of manufacturing the semiconductor device according to one aspect of the present disclosure (7);

FIG. 10 is a diagram illustrating a step of the method of manufacturing the semiconductor device according to one aspect of the present disclosure (8);

FIG. 11 is a diagram illustrating a step of the method of manufacturing the semiconductor device according to one aspect of the present disclosure (9);

FIG. 12 is a diagram illustrating a step of the method of manufacturing the semiconductor device according to one aspect of the present disclosure (10);

FIG. 13 is a diagram illustrating a step of the method of manufacturing the semiconductor device according to one aspect of the present disclosure (11);

FIG. 14 is a diagram illustrating a step of the method of manufacturing the semiconductor device according to one aspect of the present disclosure (12);

FIG. 15 is a diagram illustrating a step of the method of manufacturing the semiconductor device according to one aspect of the present disclosure (13);

FIG. 16 is a diagram illustrating a step of the method of manufacturing the semiconductor device according to one aspect of the present disclosure (14);

FIG. 17 is a diagram that depicts a modified example 1 of a method of manufacturing a semiconductor device according to one aspect of the present disclosure (1);

FIG. 18 is a diagram that depicts the modified example 1 of the method of manufacturing the semiconductor device according to one aspect of the present disclosure (2);

FIG. 19 is a diagram that depicts the modified example 1 of the method of manufacturing the semiconductor device according to one aspect of the present disclosure (3);

FIG. 20 is a schematic cross-sectional view illustrating the modified example 1 of the semiconductor device according to one aspect of the present disclosure; and

FIG. 21 is a schematic cross-sectional view illustrating a modified example 2 of a semiconductor device according to one aspect of the present disclosure.

### EMBODIMENT FOR CARRYING OUT THE INVENTION

In the following, an embodiment will be described.

### Description of Embodiment of the Present Disclosure

First, aspects of the present disclosure will be listed and described. In the following descriptions, the same reference numerals are added to the same or corresponding elements such that their descriptions are not repeated. Also, regarding crystallographic denotation in this specification, an individual orientation, a group orientation, an individual plane, and a group plane are illustrated by [ ], < >, ( ), and { }, respectively. Here, although a crystallographically negative index is usually expressed by a number with a bar “−” thereabove, a negative sign herein precedes a number to express a crystallographically negative index in this specification.

Note that various types of crystalline multi-system (polytype) exist for silicon carbide, each having different physical property values, but a 4H type is preferable for power device applications. In the following description, unless specified otherwise, silicon carbide (4H—SiC) having a 4H type crystal structure will be described.

[1] According to one aspect of the present disclosure, a semiconductor device includes: a single-crystal silicon carbide substrate; a silicon carbide epitaxial layer formed on one main surface of the single-crystal silicon carbide substrate; a recessed portion and a protruding portion formed on a surface of the silicon carbide epitaxial layer; an inclined surface formed between the recessed portion and the protruding portion; a first contact area of first conductivity type formed on the inclined surface side of a bottom surface of the recessed portion; a second contact area of second conductivity type in contact with the first contact area at the bottom surface of the recessed portion; a drift area of first conductivity type formed on an upper surface of the protruding portion; a body area of second conductivity type formed on the inclined surface between the first contact area and the drift area; a gate insulating film that covers the inclined surface; a gate electrode formed on the gate insulating film; a source electrode formed on the first contact area and the second contact area; and a drain electrode formed on the other main surface of the single-crystal silicon carbide substrate, wherein an angle of the inclined surface with respect to the one main surface of the single-crystal silicon carbide substrate is 40° or more and 70° or less.

In a single crystal of silicon carbide, the channel mobility in the in-plane direction of silicon carbide of the {0001} plane is low and the on-resistance is high. In the single crystal of silicon carbide, because the channel mobility in the {03-3-8} plane is higher than in the {0001} plane, by forming a channel in the {03-3-8} plane, the on-resistance can be decreased.

The inventors of the present application have found by research that when recessed portions, protruding portions, and inclined surfaces between the recessed portions and the protruding portions are formed on the surface of a silicon carbide epitaxial layer, and the inclined surfaces are used as channels, electrons flow from the recessed portions toward the protruding portions and thus electric field concentration is relaxed. Accordingly, by making a structure in which the inclined surfaces are the {03-3-8} planes and electrons flow from the recessed portions toward the protruding portions, the channel mobility can be increased, electric field concentration can be relaxed, and the reliability can be enhanced. Note that in the single crystal of silicon carbide, because even the {01-1-2} plane or the {01-1-4} plane other than the {03-3-8} plane has channel mobility higher than that of the {0001} plane, an inclined surface may be formed by the {01-1-2} plane or the {01-1-4} plane.

[2] A boundary between the drift area and the body area is located at the inclined surface, and the boundary is vertical to the one main surface of the single-crystal silicon carbide substrate.

[3] An impurity concentration in the body area is 1×10¹⁷ cm⁻³ or more and 3×10¹⁹ cm⁻³ or less.

[4] At a position deeper than the second contact area and the body area in the silicon carbide epitaxial layer, a semiconductor area of second conductivity type having a higher impurity concentration than in the body area is formed in contact with the second contact area and the body area.

[5] A planar shape of the recessed portion is a hexagon.

[6] The single-crystal silicon carbide substrate has a 4H type crystal structure, and the silicon carbide epitaxial layer has a 4H type crystal structure.

[7] According to another aspect of the present disclosure, a semiconductor device includes: a single-crystal silicon carbide substrate having a 4H type crystal structure; a silicon carbide epitaxial layer having a 4H type crystal structure and formed on one main surface of the single-crystal silicon carbide substrate; a recessed portion and a protruding portion formed on a surface of the silicon carbide epitaxial layer; an inclined surface formed between the recessed portion and the protruding portion; a first contact area of first conductivity type formed on the inclined surface side of a bottom surface of the recessed portion; a second contact area of second conductivity type in contact with the first contact area at the bottom surface of the recessed portion; a drift area of first conductivity type formed on an upper surface of the protruding portion; a body area of second conductivity type formed on the inclined surface between the first contact area and the drift area; a gate insulating film that covers the inclined surface; a gate electrode formed on the gate insulating film; a source electrode formed on the first contact area and the second contact area; and a drain electrode formed on the other main surface of the single-crystal silicon carbide substrate, wherein an angle of the inclined surface with respect to the one main surface of the single-crystal silicon carbide substrate is 40° or more and 70° or less, wherein a boundary between the drift area and the body area is located at the inclined surface, wherein the boundary is vertical to the one main surface of the single-crystal silicon carbide substrate, and wherein an impurity concentration in the body area is 1×10¹⁷ cm³ or more and 3×10¹⁹ cm³ or less.

### Details of Embodiment of the Present Disclosure

In the following, an embodiment of the present disclosure (which is hereinafter referred to as the “present embodiment”) will be described in detail, but the present embodiment is not limited to the following.

### Silicon Carbide Semiconductor Device

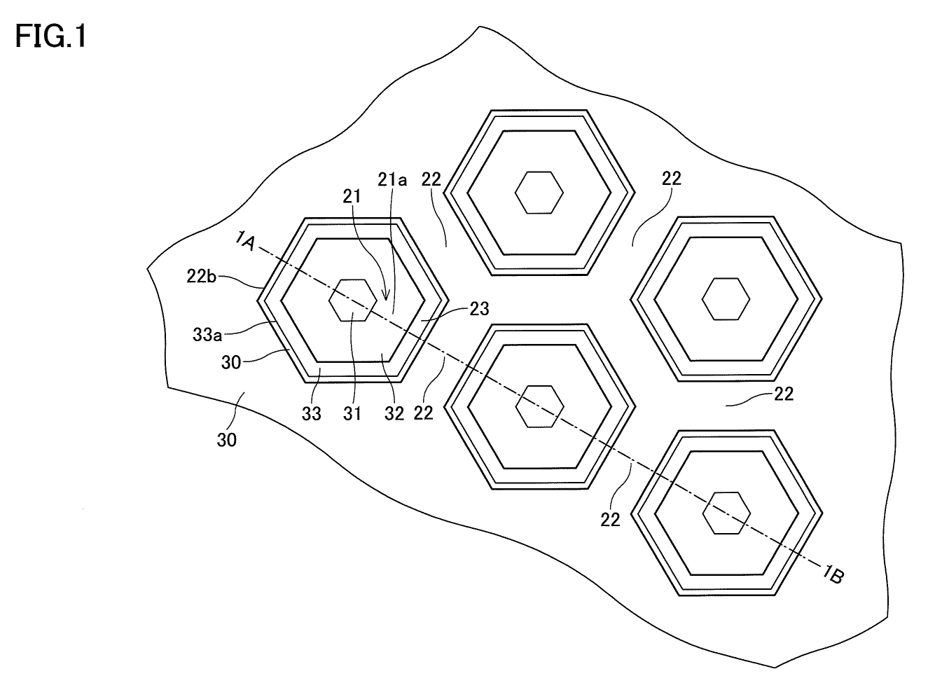

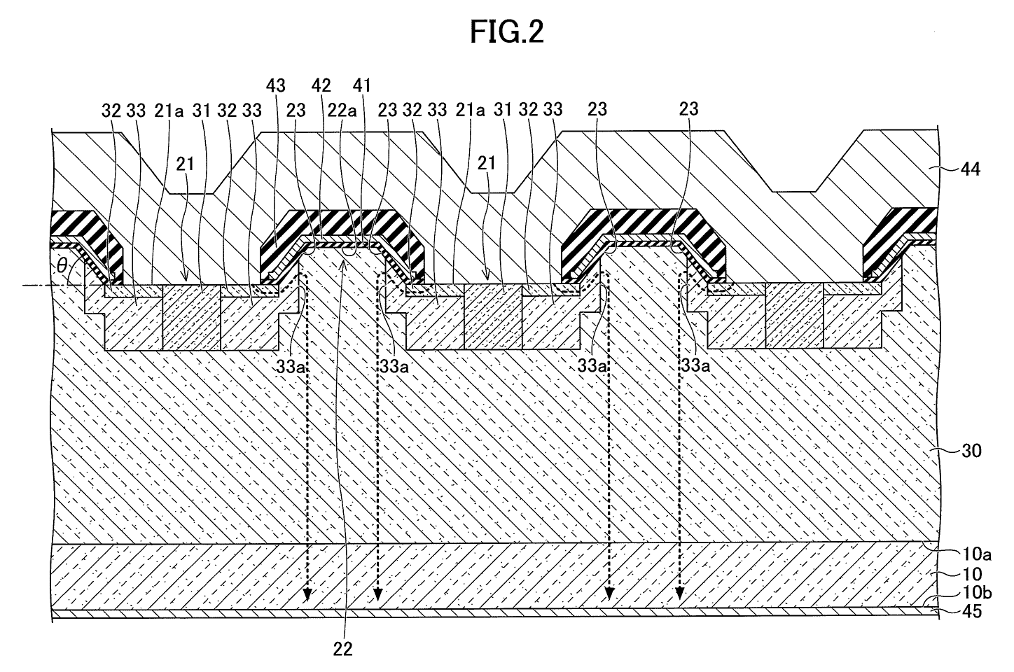

In the following, a silicon carbide semiconductor device according to the present embodiment will be described with reference to FIG. 1 and FIG. 2. Note that FIG. 1 is a top view of a semiconductor portion of the semiconductor device according to the present embodiment, and FIG. 2 is a cross-sectional view of the semiconductor device taken along a portion corresponding to the one-dot chain line 1A-1B in FIG. 1. Note that in FIG. 1, descriptions of a gate insulating film 41, a gate electrode 42, an interlayer insulating film 43, a source electrode 44, and the like illustrated in FIG. 2 are omitted.

The semiconductor device according to the present embodiment is a vertical MOSFET having a structure in which a plurality of recessed portions and protruding portions are formed on the surface of a silicon carbide epitaxial layer formed on one main surface of a silicon carbide substrate and inclined surfaces are included between the recessed portions and the projecting portions.

Specifically, the silicon carbide epitaxial layer for foaming an n drift area 30 and the like is formed on one main surface 10a of an n-type single-crystal silicon carbide substrate 10, and a plurality of protruding portions 21 and recessed portions 22 are formed on the surface of this silicon carbide epitaxial layer. The bottom surfaces of the recessed portions 21 are formed in a hexagonal shape, and the protruding portions 22 are formed so as to surround the peripheries of the hexagonal recessed portions 21. Also, inclined surfaces 23 are formed between the recessed portions 21 and the projecting portions 22, and the inclined surfaces 23 are the {03-3-8} planes with high channel mobility. Therefore, the semiconductor device according to the present embodiment has a structure in which the protruding portions 22 are formed between the recessed portions 21, and the inclined surfaces 23 are formed on both sides of the protruding portions 22. In FIG. 1, areas where p+ contact areas 31 and n⁺ contact areas 32 are formed, which will be described later, are the recessed portions 21. Areas where p body areas 33 are formed and areas where parts of the n drift area 30 are formed are the inclined surfaces 23. Areas where the n drift area 30 outside the inclined surfaces 23 is formed are the protruding portions 22. Solid lines 22b indicate the boundaries between the inclined surfaces 23 and the protruding portions 22.

Note that according to the present embodiment, the single-crystal silicon carbide substrate 10 has a 4H type crystal structure, and the silicon carbide epitaxial layer formed on the one main surface 10a of the single-crystal silicon carbide substrate 10 also has a 4H type crystal structure.

Note that the angle of the {03-3-8} plane with respect to the {0001} plane is about 54.7°. Also, in a single crystal of silicon carbide, because even the {01-1-2} plane or the {01-1-4} plane other than the {03-3-8} plane has channel mobility higher than that of the {0001} plane, the inclined surfaces 23 may be formed by these planes. The angle of the {01-1-2} plane with respect to the {0001} plane is 62.1°, and the angle of the {01-1-4} plane with respect to the {0001} plane is 43.3°.

According to the present embodiment, angles θ of the inclined surfaces 23 with respect to the one main surface 10a of the single-crystal silicon carbide substrate 10 or the like is preferably 40° or more and 70° or less. This is because, in a case where the angles θ of the inclined surfaces 23 with respect to the one main surface 10a of the single-crystal silicon carbide substrate 10 or the like are less than 40°, the inclined surfaces 23 are widened and the semiconductor device becomes large; and in a case where the angles θ exceed 70°, the p body areas 33, which will be described later below, are not easily formed by ion-implantation.

The p⁺ contact areas 31 are formed on the central portions of the bottom surfaces 21a of the recessed portions 21, and the n⁺ contact areas 32 are formed around the p⁺ contact areas 31 at the bottom surfaces 21a of the recessed portions 21. Also, the p body areas 33 are formed at positions deeper than the n⁺ contact areas 32. The p body areas 33 are in contact with the lower ends of the n⁺ contact areas 32. At the bottom surfaces 21a of the recessed portions 21, the n drift area 30 is formed at a position deeper than the p⁺+ contact areas 31 and the p body areas 33. The protruding portions 22 are formed by the n drift area 30, and at the inclined surfaces 23, the p body areas 33 and the n drift area 30 are in contact with each other.

In the semiconductor device according to the present embodiment, the impurity concentration of the n-type single-crystal silicon carbide substrate 10 is 1×10¹⁹ cm⁻³, and the impurity concentration of the n drift area 30 is from 1×10¹⁵ to 2×10¹⁶ cm⁻³. Also, the impurity concentration of the p⁺ contact areas 31 is 2×10²⁰ cm⁻³, and the impurity concentration of the n⁺ contact area 32 is 1×10²⁰ cm⁻³. The impurity concentration of the p body areas 33 is 1×10¹⁷ cm⁻³ or more and 3×10¹⁹ cm⁻³ or less, and is formed to be, for example, about 5×10¹⁷ cm⁻³.

Also, in the semiconductor device according to the present embodiment, the gate insulating film 41 is formed on upper surfaces 22a of the protruding portions 22, the inclined surfaces 23, and the bottom surfaces 21a of the recessed portions 21 near the inclined surfaces 23, and the gate electrode 42 is formed on the gate insulating film 41. Therefore, via the gate insulating film 41, the gate electrode 42 is formed over the upper surfaces 22a of the protruding portions 22, the inclined surfaces 23, and the bottom surfaces 21a of the recessed portions 21 near the inclined surfaces 23.

Also, the interlayer insulating film 43 is formed over the gate electrode 42 and the gate insulating film 41, and the gate electrode 42 is covered with the interlayer insulating film 43. Further, the source electrode 44 is formed on the bottom surfaces 21a of the recessed portions 21, and the source electrode 44 is in contact with the p⁺ contact areas 31 and the n⁺ contact areas 32 at the bottom surfaces 21a of the recessed portions 21. The source electrode 44 is also formed on the interlayer insulating film 43, and the bottom surfaces 21a of the plurality of recessed portions 21 are connected by a single source electrode 44. Also, on the other main surface 10b of the single-crystal silicon carbide substrate 10, the drain electrode 45 is formed.

According to the present embodiment, boundaries 33a between the p body areas 33 and the n drift area 30 are located at the inclined surfaces 23. Also, near the inclined surfaces 23, the boundaries 33a between the p body areas 33 and the n drift area 30 are vertical to the one main surface 10a of the single-crystal silicon carbide substrate 10 or the like. According to the present embodiment, for the one main surface 10a and the other main surface 10b of the single-crystal silicon carbide substrate 10, an off substrate, whose off angle with respect to the {0001} plane (c plane) of the single-crystal silicon carbide substrate 10 is −3° or more and 3° or less, is used. Because the inclined surfaces 23 are formed by the {03-3-8} planes having high channel mobility, the angles θ of the inclined surfaces 23 with respect to the one main surface 10a of the single-crystal silicon carbide substrate 10 or the like are about 55°±3°. Therefore, the angles formed by the boundaries 33a, between the p body areas 33 and the n drift area 30, and the inclined surfaces 23 are wider on the n drift area 30 side than on the p body areas 33 side.

According to the present embodiment, when a positive voltage is applied to the gate electrode 42, channels are formed in the inclined surfaces 23 of the p body areas 33, and the n⁺ contact areas 32 and the n drift area 30 are electrically connected via the p body areas 33. As a result, electrons serving as carriers sequentially flow from the source electrode 44, the n⁺ contact areas 32, the p body areas 33, the n drift area 30, the single-crystal silicon carbide substrate 10, to the drain electrode 45 in this order as indicated by the broken line arrows. Therefore, in the p body areas 33, where the channels are formed, electrons flow along the inclined surfaces 23, where the channels are formed, toward the upper surfaces 22a of the protruding portions 22. Upon entering the n drift area 30, the electrons flow toward the single-crystal silicon carbide substrate 10 on which the drain electrode 45 is formed.

According to the present embodiment, because the inclined surfaces 23 of the p body areas 33 where the channels are formed are the {03-3-8} planes with high channel mobility, the on-resistance can be reduced. Also, because the positions where the source electrode 44 is in contact with the n⁺ contact areas 32 are lower than the inclined surfaces 23 of the p body areas 33 where the channels are formed, the concentration of the electric field in the gate insulating film 41 can be relaxed, and the reliability of the semiconductor device can be enhanced.

### Method of Manufacturing Semiconductor Device

Next, a method of manufacturing the semiconductor device according to the present embodiment will be described.

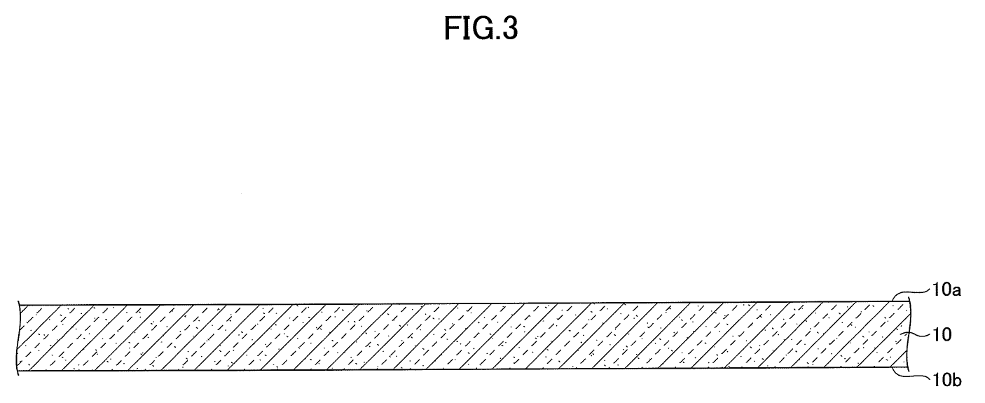

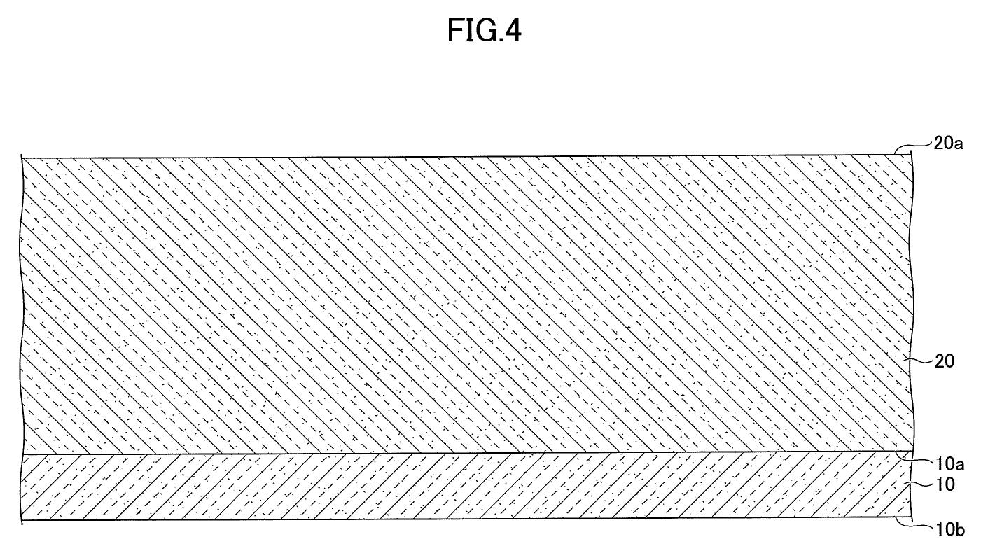

First, as illustrated in FIG. 3, the n-type single-crystal silicon carbide substrate 10 is prepared, and as illustrated in FIG. 4, on the one main surface 10a of the single-crystal silicon carbide substrate 10, the n-type silicon carbide epitaxial layer 20 is formed. The silicon carbide epitaxial layer 20 is formed in order to form the n drift area 30, the p⁺ contact areas 31, the n⁺ contact areas 32, and the p body areas 33. Specifically, by implanting ions into the silicon carbide epitaxial layer 20, the p⁺ contact areas 31, the n⁺ contact areas 32, and the p body areas 33 are formed, and an area where the ions are not implanted in the silicon carbide epitaxial layer 20 becomes the n drift area 30.

The silicon carbide epitaxial layer 20 is formed by epitaxial growth using CVD (chemical vapor deposition). At this time, a mixed gas of silane (SiH₄) and propane (C₃H₈) is used as a material gas, and hydrogen gas (H₂) is used as a carrier gas. Nitrogen (N), phosphorus (P), or the like is used as an impurity element whose conductivity type is for n-type, for example. The concentration of the impurity element doped in the silicon carbide epitaxial layer 20 is preferably greater than or equal to 5×10¹⁵ cm⁻³ and less than or equal to 5×10¹⁶ cm⁻³. In this way, the silicon carbide epitaxial layer 20 that has a surface 20a is formed on the one main surface 10a of the single-crystal silicon carbide substrate 10. According to the present embodiment, N is used as the impurity element for n-type, and the concentration of the impurity element in the n-type single-crystal silicon carbide substrate 10 is 3×10¹⁸ cm⁻³.

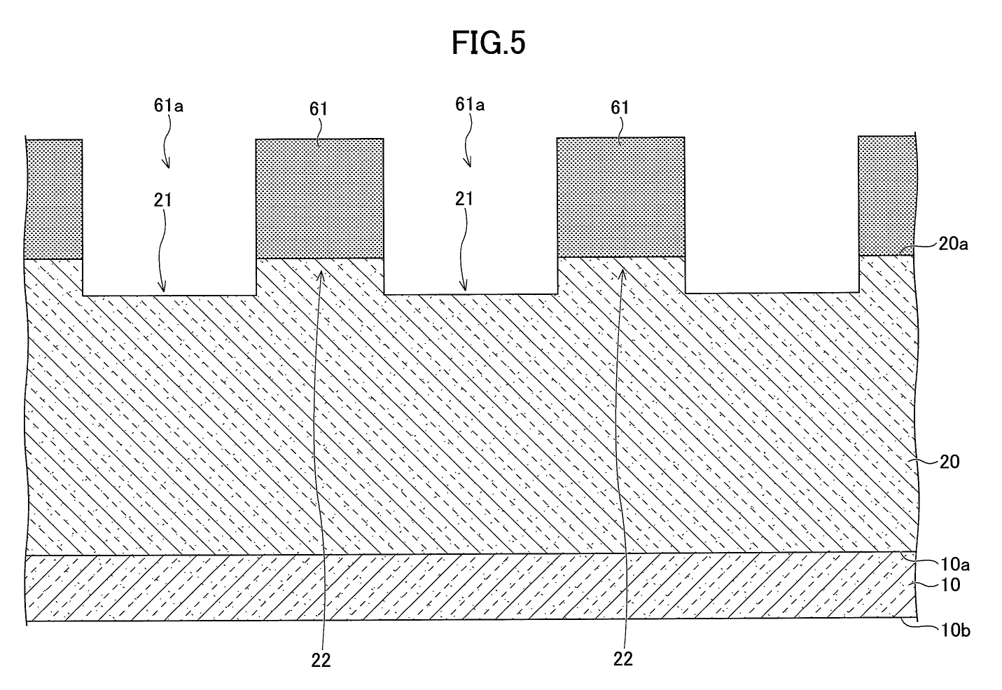

Next, as illustrated in FIG. 5, the plurality of recessed portions 21 are formed on the surface 20a of the silicon carbide epitaxial layer 20. Specifically, a photoresist is applied to the surface 20a of the silicon carbide epitaxial layer 20, and exposure and development are performed by an exposure device to form an etching mask 61 having openings 61a at the areas where the recessed portions 21 are to be formed. Thereafter, the silicon carbide epitaxial layer 20 at the areas where the etching mask 61 is not formed is partially removed from the surface 20a by a dry etching process such as RIE to form the plurality of recessed portions 21. As a method of dry etching such as RIE, ICP (Inductive Coupled Plasma) —RIE or the like can be used, and as an etching gas, SF₆ or a mixed gas of SF₆ and O₂ can be used. As a result, the plurality of recessed portions 21 and protruding portions 22 are formed, and the side walls of the recessed portions 21 are formed to be substantially vertical to the one main surface 10a of the single-crystal silicon carbide substrate 10. The recessed portions 21 formed as described above have a hexagonal shape when viewed from above.

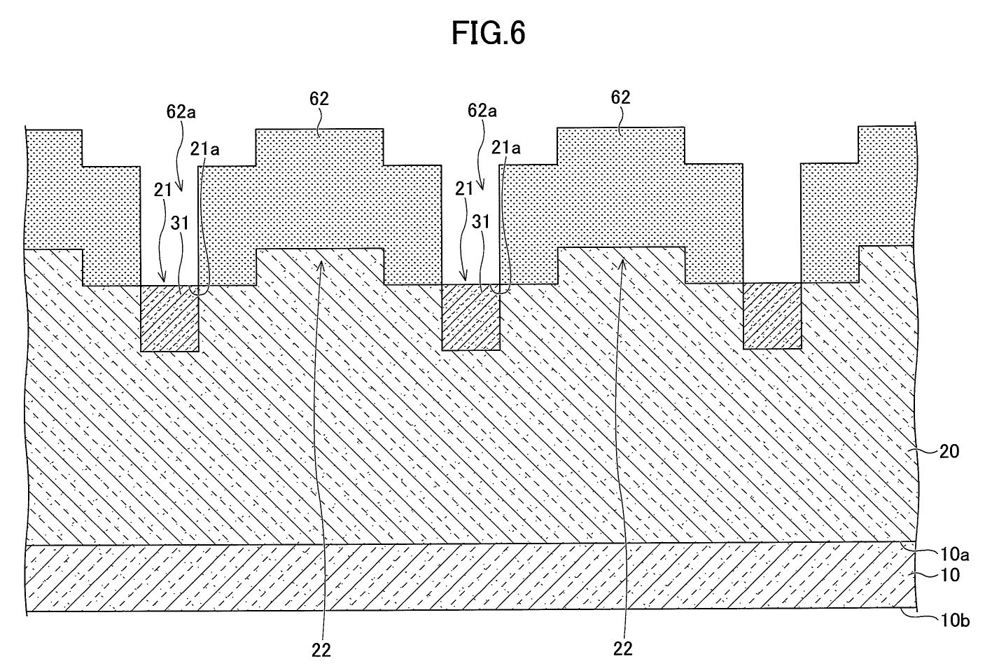

Next, as illustrated in FIG. 6, by ion-implanting an impurity element for p-type into the central portions of the bottom surfaces 21a of the recessed portions 21, the p⁺ contact areas 31 are formed. Specifically, after removing the etching mask 61, an ion implantation mask 62 having openings 62a at areas where the p⁺ contact areas 31 are to be formed is formed. Thereafter, by ion-implanting the impurity element for p-type into the silicon carbide epitaxial layer 20 at the areas where the openings 62a are formed, the p⁺ contact areas 31 are formed. As the impurity element for p-type, Al or the like can be used, and ion implantation is carried out by adjusting the dose amount and the acceleration voltage so that the impurity concentration in the p⁺ contact areas 31 is a desired concentration to a desired depth. According to the present embodiment, the impurity concentration in the p⁺ contact areas 31 is 1×10²⁰ cm⁻³.

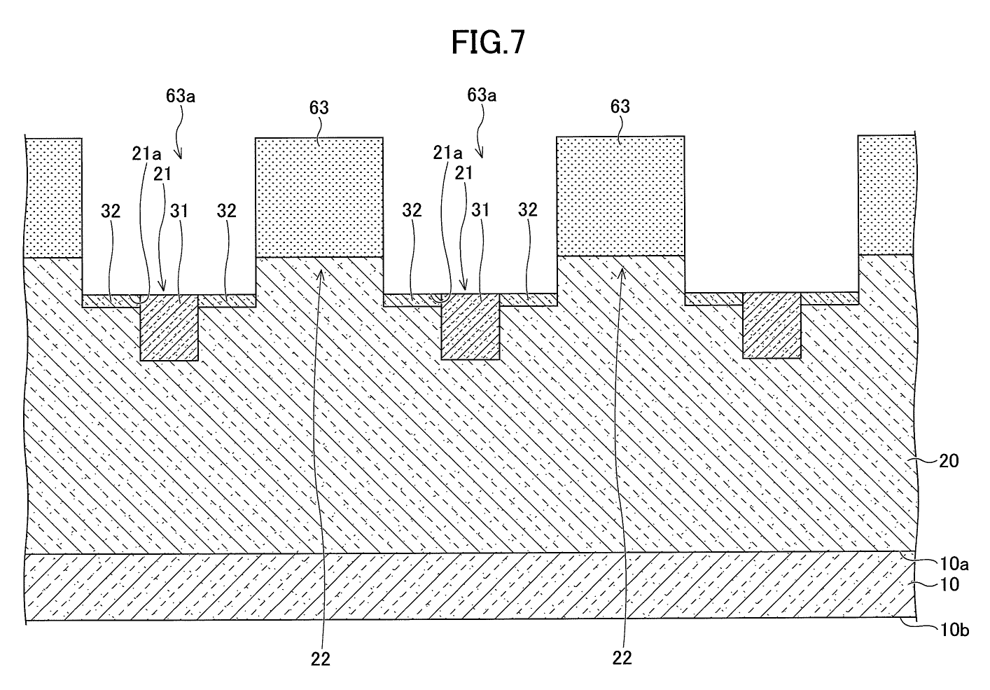

Next, as illustrated in FIG. 7, by ion implanting an impurity element for n-type around the p⁺ contact areas 31 at the bottom surfaces 21a of the recessed portions 21, the n⁺ contact areas 32 are formed. Specifically, after removing the ion implantation mask 62, an ion implantation mask 63 having openings 63a at the bottom surfaces 21a of the recessed portions 21 is formed. Thereafter, by ion-implanting the impurity element for n-type into the silicon carbide epitaxial layer 20 at the areas where the openings 63a are formed, the n⁺ contact areas 32 are formed. Nitrogen (N), phosphorus (P), or the like is used as the impurity element whose conductivity type is for n-type. The n⁺ contact areas 32 are formed in areas shallower than the p⁺ contact areas 31. Thus, although the impurity element for n-type is also implanted into the shallow areas of the p⁺ contact areas 31, because the concentration of the impurity element implanted into the n⁺ contact areas 32 is lower than the concentration of the impurity element in the p⁺ contact areas 31, the p-type is maintained. Therefore, ion implantation is carried out by adjusting the dose amount and the acceleration voltage so that the impurity concentration in the n⁺ contact areas 32 is a desired concentration to a desired depth. According to the present embodiment, the impurity concentration in the n⁺ contact areas 32 is 5×10¹⁹ cm⁻³.

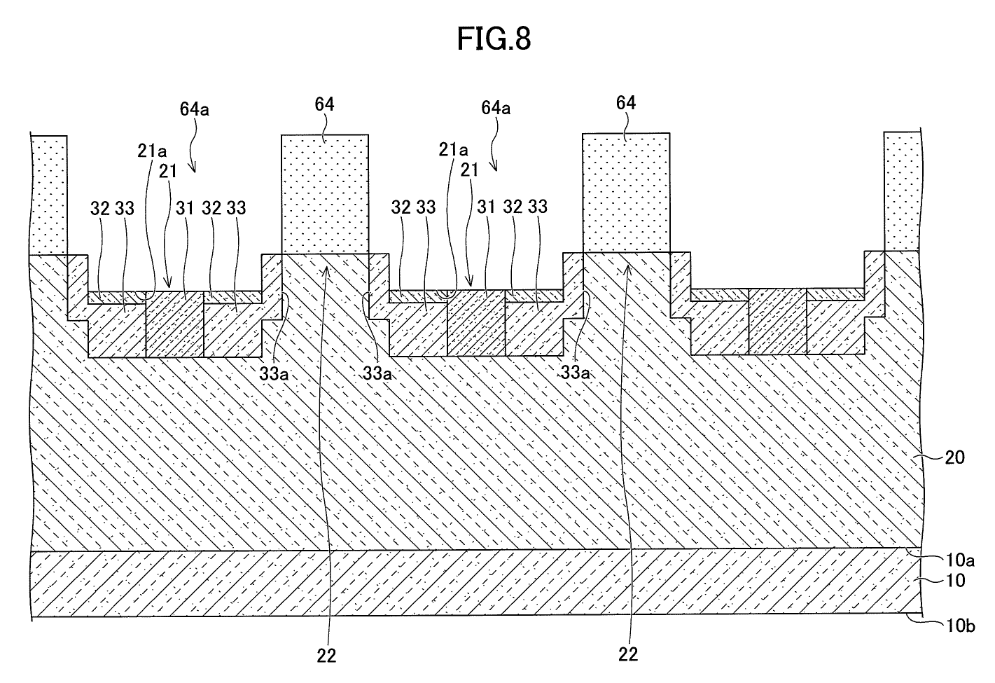

Next, as illustrated in FIG. 8, by ion-implanting an impurity element for p-type into areas deeper than the n⁺ contact areas 32 at the bottom surfaces 21a of the recessed portions 21 and parts of the protruding portions 22 around the recessed portions 21, the p body areas 33 are formed. Specifically, after removing the ion implantation mask 63, an ion implantation mask 64 having openings 64a at the areas where the p body areas 33 are to be formed is formed. Thereafter, by ion-implanting the impurity element for p-type into the silicon carbide epitaxial layer 20 at the areas where the openings 64a are formed, the p body areas 33 are formed. As a result, the p body areas 33 are formed in areas deeper than the n⁺ contact areas 32 and parts of the protruding portions 22 near the recessed portions 21.

In this step, ion implantation is carried out by adjusting the dose amount and the acceleration voltage so that the impurity concentration in the p body areas 33 is a desired concentration to a desired depth. According to the present embodiment, the impurity concentration in the p body areas 33 is 2×10¹⁷ cm⁻³.

In this ion implantation, although the impurity element for p-type is also implanted into the n⁺ contact areas 32, because the concentration of the impurity element implanted into the p body areas 33 is lower than the concentration of the impurity element in the n⁺ contact areas 32, the n-type is maintained. Although the impurity element for p-type is also implanted into the p⁺ contact areas 31, it remains the p-type because of being the same p-type. As described above, by ion-implanting impurity elements into the silicon carbide epitaxial layer 20, the p⁺ contact areas 31, the n⁺ contact areas 32, and the p body areas 33 are formed. Therefore, in the silicon carbide epitaxial layer 20, the area where the impurity elements are not ion-implanted becomes the n drift area 30. In the following, in the silicon carbide epitaxial layer 20, an area where the impurity elements are not ion-implanted will be described as the n drift area 30. In this way, because the p body areas 33 are formed by implanting ions into the silicon carbide epitaxial layer 20, the boundaries 33a between the n drift area 30 and the p body areas 33 are formed to be substantially vertical to the one main surface 10a of the single-crystal silicon carbide substrate 10.

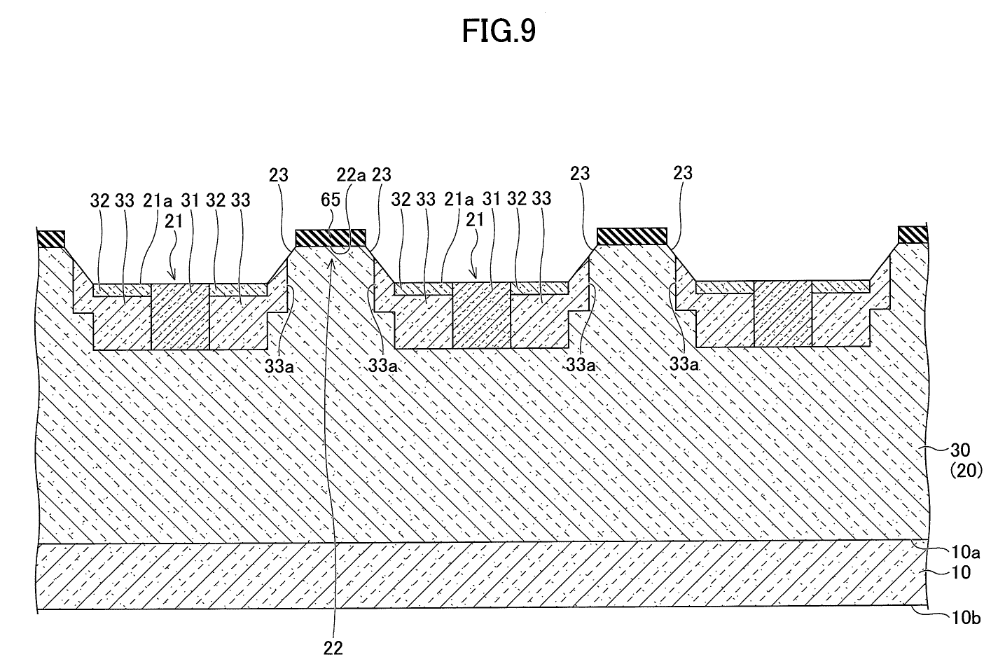

Next, as illustrated in FIG. 9, by performing thermal etching, the inclined surfaces 23 to be the {03-3-8} planes are formed between the recessed portions 21 and the protruding portions 22. Specifically, after removing the ion implantation mask 64, a silicon oxide film is deposited on the entire surface by CVD or the like. Thereafter, a photoresist is applied on the deposited silicon oxide film, and exposure and development by an exposure device are performed. As a result, an unillustrated resist pattern is formed on the silicon oxide film at the areas where a thermal etching mask 65 is to be formed. Thereafter, the silicon oxide film at the areas where the resist pattern is not formed is removed by a dry etching process such as RIE to expose the bottom surfaces 21a and the side surfaces of the recessed portions 21 and parts of the upper surfaces 22a of the protruding portions 22 near the recessed portions 21. Thereafter, by removing the unillustrated resist pattern, the thermal etching mask 65 is formed by the remaining silicon oxide film. The thermal etching mask 65 is formed on the n drift area 30 at the upper surfaces 22a of the protruding portions 22 and parts of the n drift area 30 are exposed between the thermal etching mask 65 and the boundaries 33a.

Thereafter, thermal etching is performed using the thermal etching mask 65 as a mask. In this thermal etching, a mixed gas of oxygen gas and chlorine gas is used as a reaction gas, for example, at a temperature of 700° C. or more and 1000° C. or less. As a result, the {03-3-8} planes, which are predetermined crystal planes, are exposed at the n drift area 30 at the areas where the thermal etching mask 65 is not formed, the p⁺ contact areas 31, the n⁺ contact areas 32, and parts of the p body areas 33. In this way, by thermal etching, the {03-3-8} planes to be the inclined surfaces 23 can be formed between the recessed portions 21 and the protruding portions 22.

In this thermal etching, in a reaction formula represented by SiC+mO₂+nCl₂→SiClₓ+COy (where m, n, x, and y are positive numbers), a main reaction proceeds when x and y satisfy the conditions of 0.5≤x≤2.0 and 1.0≤y≤2. Also, in a case of conditions in which x=4 and y=2, the reaction (thermal etching) proceeds at the highest rate. Note that the reaction gas may contain a carrier gas in addition to chlorine gas and oxygen gas as described above. As the carrier gas, for example, nitrogen (N₂) gas, argon gas, helium gas, or the like can be used. As described above, when thermal etching is performed at a temperature of 700° C. or more and 1000° C. or less, the etching rate of SiC is about 70 μm/hr, for example. Also, when silicon oxide (SiO₂) is used for the thermal etching mask 65, the selection ratio of SiC to SiO₂ is extremely large. Therefore, when etching SiC, the thermal etching mask 65 formed of SiO₂ is not substantially etched.

The crystal planes of the inclined surfaces 23 formed by thermal etching in this manner are the {03-3-8} planes. That is, in the etching under the above described conditions, the {03-3-8} planes, which are the crystal planes having the slowest etching rate, are self-formed as the inclined surfaces 23 between the recessed portions 21 and the protruding portions 22. According to the present embodiment, the boundaries 33a, between the n drift area 30 and the p body areas 33, vertical to the one main surface 10a of the single-crystal silicon carbide substrate 10 are formed so as to be located on the inclined surfaces 23. Note that the inclined surfaces 23 may be formed of the {01-1-2} planes, the {01-1-4} planes, or the like other than the {03-3-8} planes.

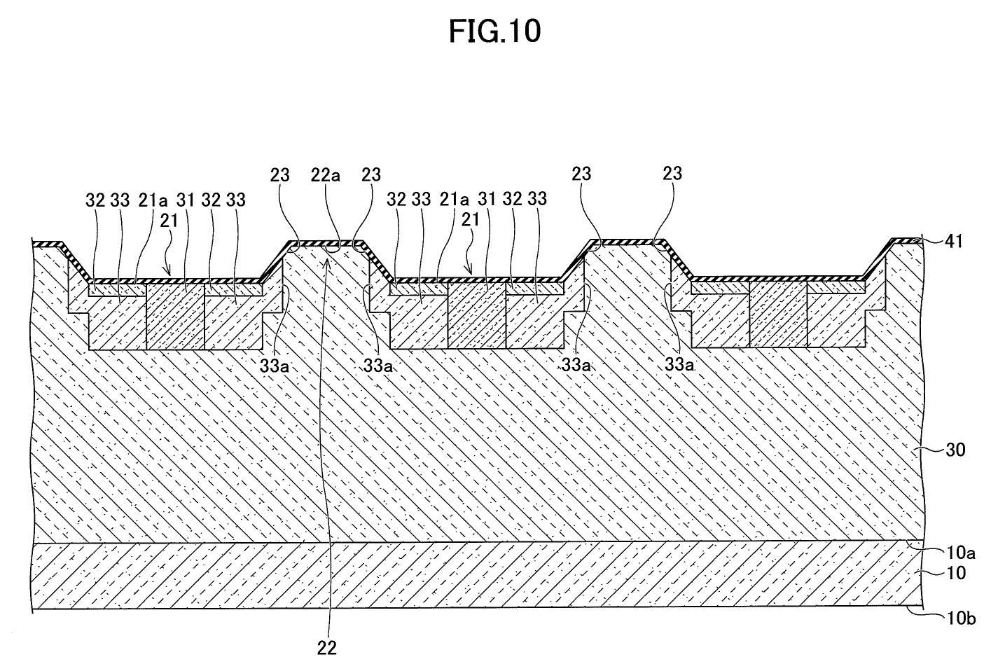

Next, as illustrated in FIG. 10, after removing the thermal etching mask 65, the gate insulating film 41 is formed on the bottom surfaces 21a of the recessed portions 21, the upper surfaces 22a of the protruding portions 22, and the surfaces of the inclined surfaces 23. The gate insulating film 41 is formed by thermally oxidizing the surface of silicon carbide forming the bottom surfaces 21a of the recessed portions 21, the upper surfaces 22a of the protruding portions 22, and the inclined surfaces 23.

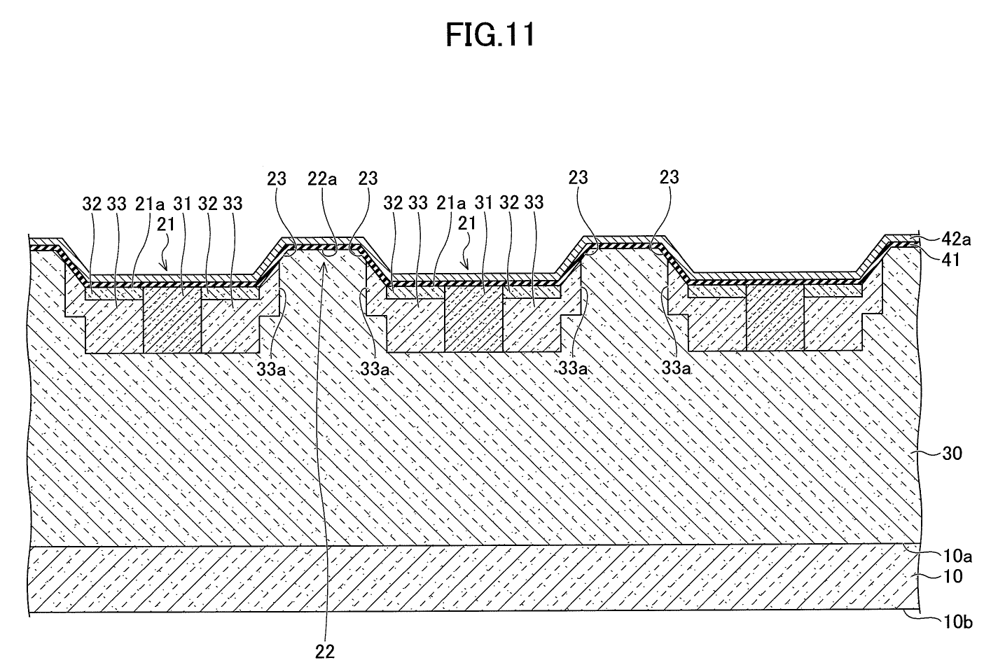

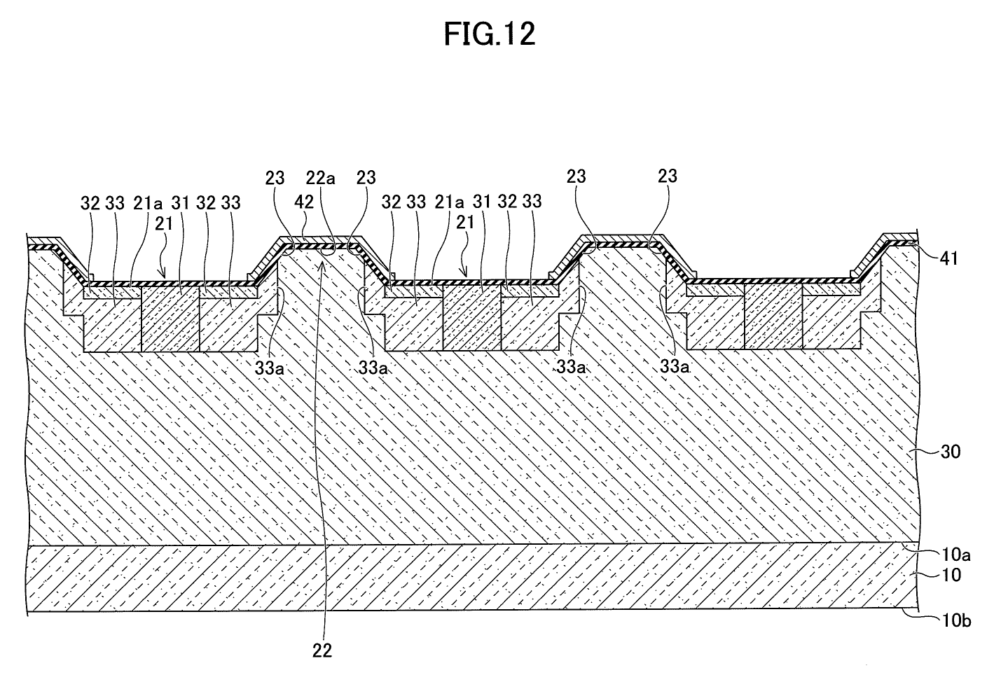

Next, as illustrated in FIG. 11, a conductive film 42a is deposited on the gate insulating film 41, and the conductive film 42a is processed as illustrated in FIG. 12 to form the gate electrode 42. Specifically, as illustrated in FIG. 11, the conductive film 42a is deposited by sputtering a metal film or the like on the gate insulating film 41, and thereafter, on the conductive film 42a, a photoresist is applied, and exposure and development by an exposure device are performed. As a result, an unillustrated resist pattern is formed on the areas of the conductive film 42a where the gate electrode 42 is to be formed. Thereafter, the conductive film 42a at the areas where the resist pattern is not formed is removed by etching. As a result, as illustrated in FIG. 12, the gate electrode 42 is formed via the gate insulating film 41 over the upper surfaces 22a of the protruding portions 22, the inclined surfaces 23, and the bottom surfaces 21a of the recessed portions 21 near the inclined surfaces 23. Thereafter, the unillustrated resist pattern is removed.

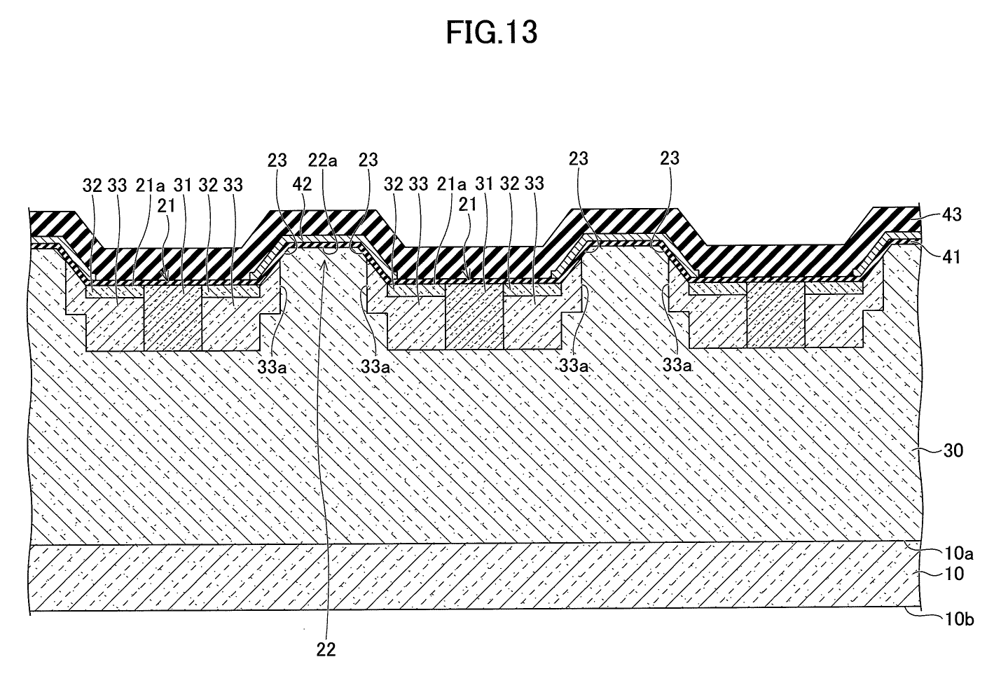

Next, as illustrated in FIG. 13, the interlayer insulating film 43 is formed on the gate insulating film 41 and the gate electrode 42. For the interlayer insulating film 43, an insulating silicon oxide film or the like can be used.

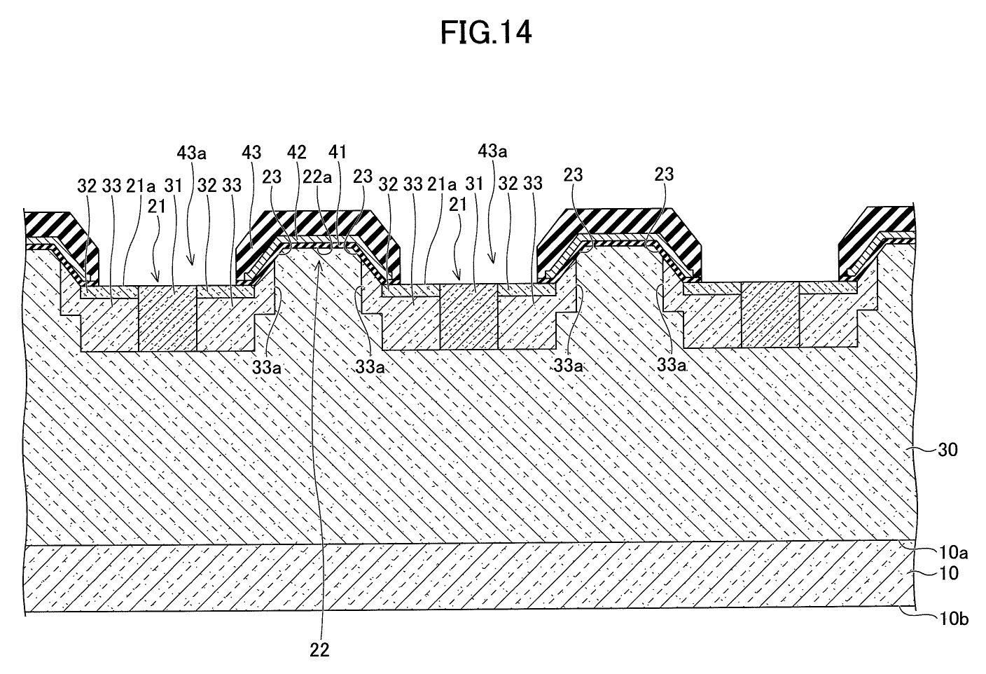

Next, as illustrated in FIG. 14, parts of the gate insulating film 41 and the interlayer insulating film 43 are removed to form contact holes 43a, and the p⁺ contact areas 31 and parts of the n⁺ contact areas 32 at the bottom surfaces 21a of the recessed portions 21 are exposed. Specifically, a photoresist is applied onto the interlayer insulating film 43, and exposure and development are performed by an exposure device to form, on the interlayer insulating film 43, an unillustrated resist pattern having openings at the areas where the contact holes 43a are to be formed. Thereafter, by a dry etching process such as RIE, the gate insulating film 41 and the interlayer insulating film 43 at the areas where the resist pattern is not formed are removed by a dry etching process such as RIE to form the contact holes 43a. In this way, by forming the contact holes 43a, the p⁺ contact areas 31 and parts of the n⁺ contact areas 32 are exposed at the bottom surfaces 21a of the recessed portions 21.

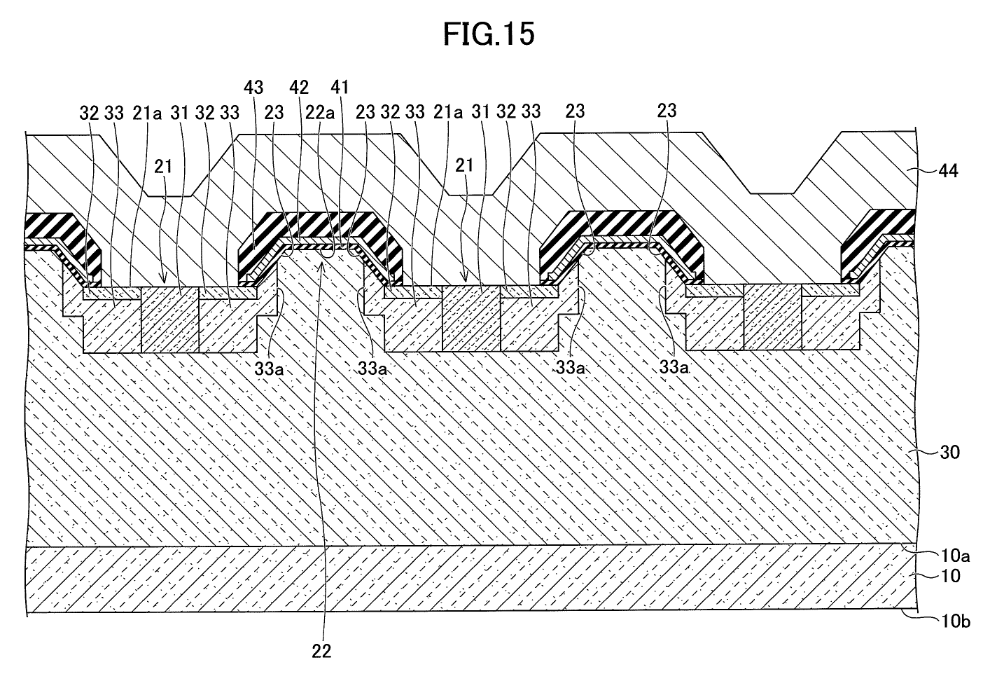

Next, as illustrated in FIG. 15, the source electrode 44 is formed, for example, by a conductive film such as a metal film on the interlayer insulating film 43, the p⁺ contact areas 31, and the n⁺ contact areas 32. As a result, the source electrode 44 that is in contact with the p⁺ contact areas 31 and the n⁺ contact areas 32 on the bottom surfaces 21a of the recessed portions 21 where the contact holes 43a are formed is formed.

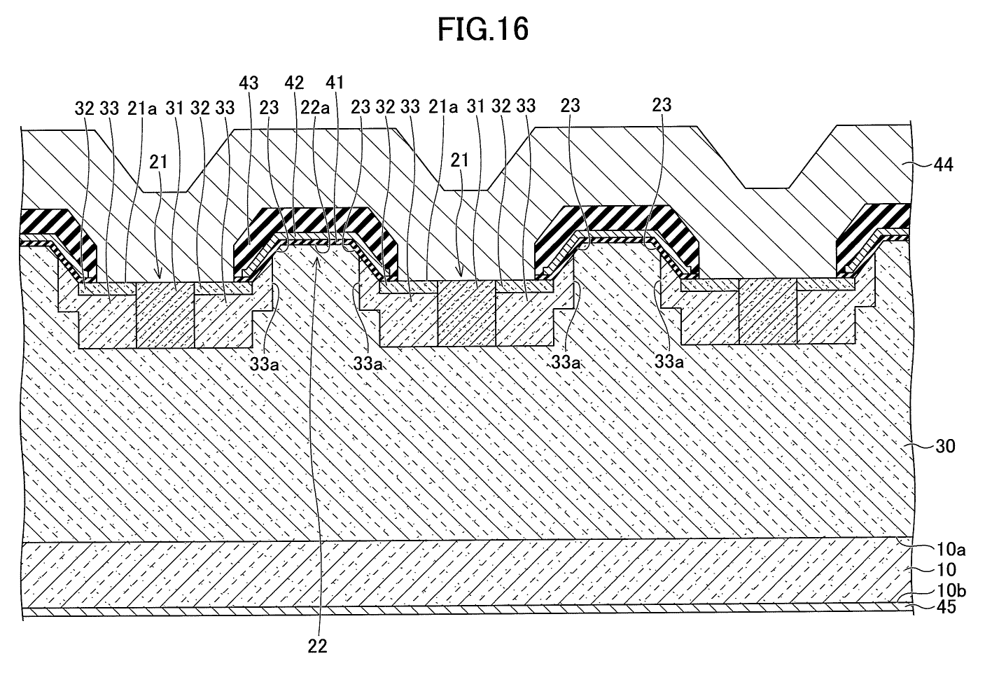

Next, as illustrated in FIG. 16, the drain electrode 45 is formed, for example, by a conductive film such as a metal film on the other main surface 10b of the single-crystal silicon carbide substrate 10. As a result, the semiconductor device according to the present embodiment can be manufactured.

### Modified Example 1

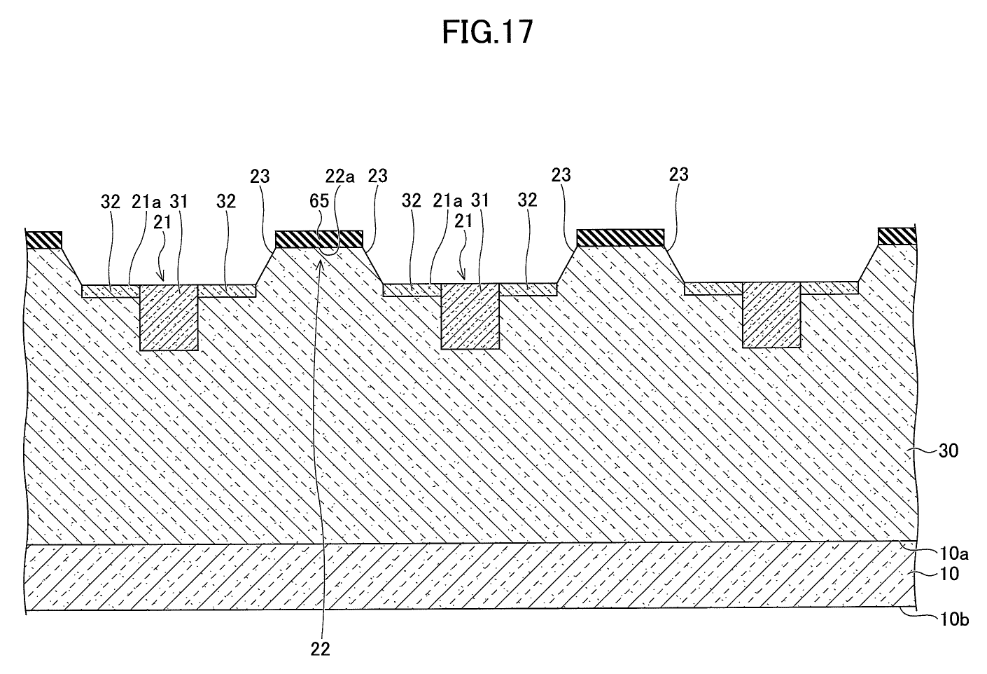

A method of manufacturing a semiconductor device according to the present embodiment may be a method in which after the step illustrated in FIG. 7, thermal etching is performed, ion implantation for forming the p body areas 33 is performed, and thermal etching is performed again. More specifically, after the step illustrated in FIG. 7, the ion implantation mask 63 is removed, the thermal etching mask 65 is formed as illustrated in FIG. 17, and thermal etching is performed. As a result, the inclined surfaces 23 are formed between the recessed portions 21 and the protruding portions 22.

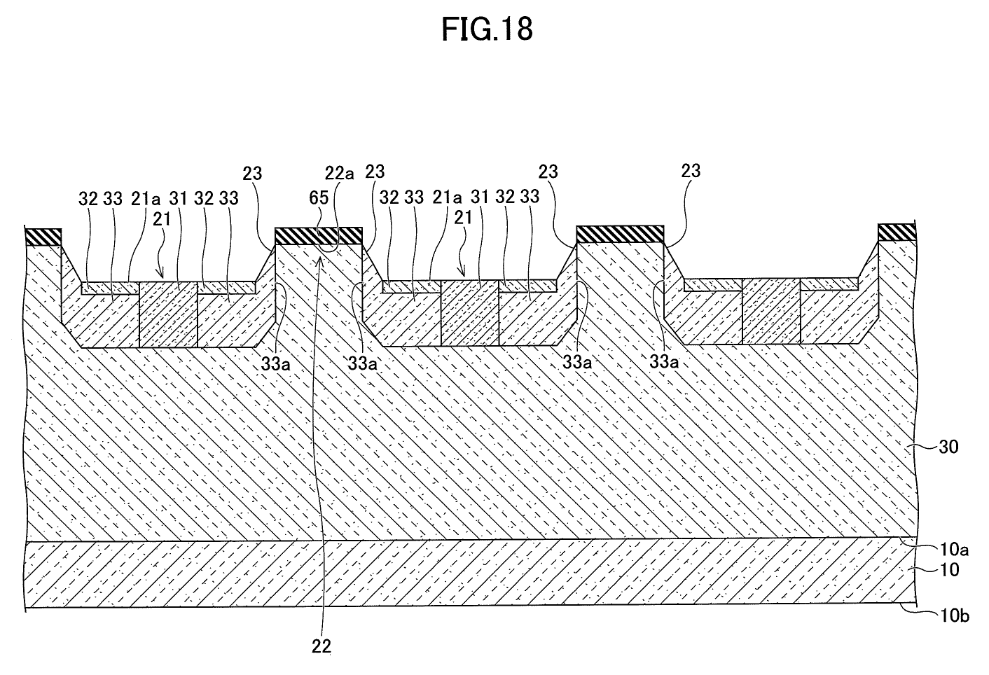

Next, as illustrated in FIG. 18, by ion-implanting an impurity element for p-type into the areas deeper than the n⁺ contact areas 32 at the bottom surfaces 21a of the recessed portions 21 and into the inclined surfaces 23, the p body areas 33 are formed. As a result, the boundaries 33a between the p body areas 33 and the n drift area 30 between the thermal etching mask 65 and the n drift area 30 are formed to be vertical to the one main surface 10a of the single-crystal silicon carbide substrate 10.

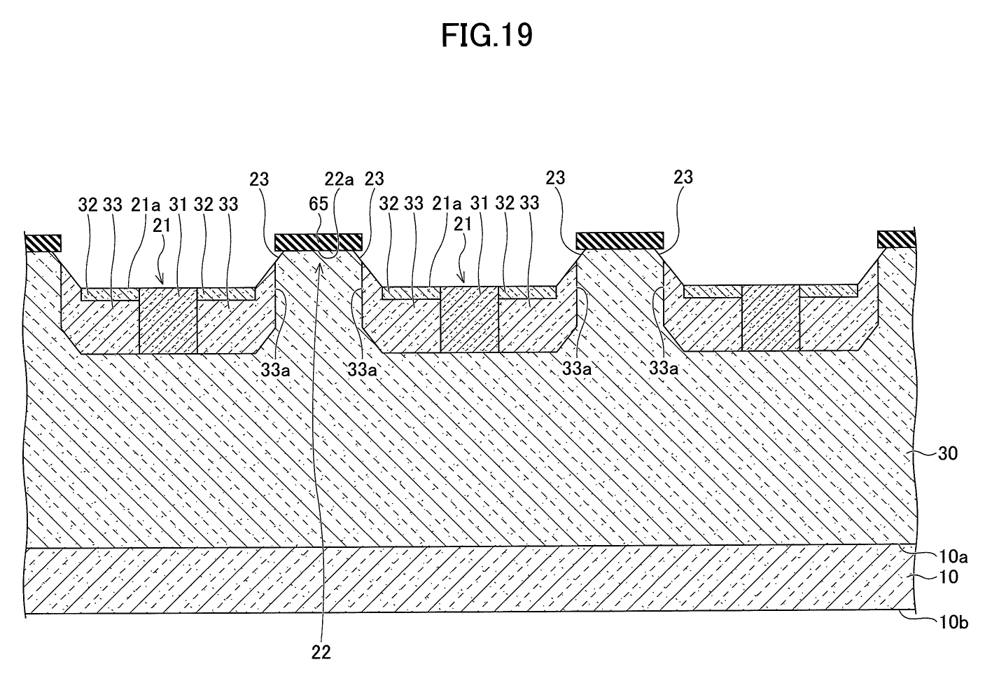

Next, as illustrated in FIG. 19, thermal etching is performed again. As a result, even at the lower portions of the edge of the thermal etching mask 65, a semiconductor part at the inclined surfaces 23 are removed and the boundaries between the n drift area 30 and the p body areas 33 are formed to be located at the inclined surfaces 23. As a result, the inclined surfaces 23 to be the {03-3-8} planes can be formed between the recessed portions 21 and the protruding portions 22.

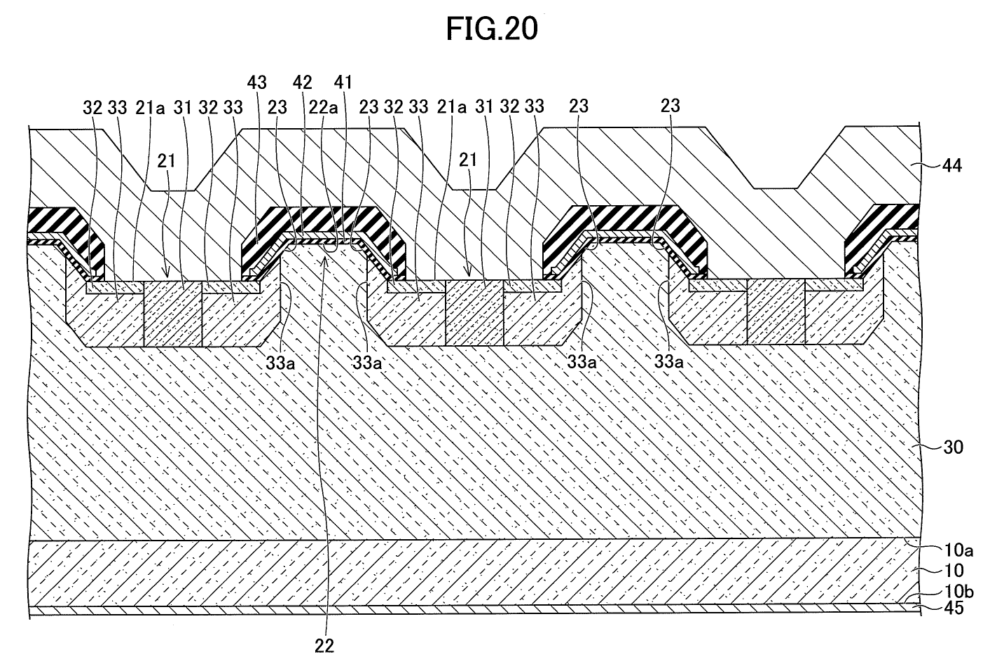

Thereafter, by performing the steps after the step illustrated in FIG. 10, the semiconductor device having the structure illustrated in FIG. 20 can be manufactured. In this semiconductor device, under the inclined surfaces 23, the boundaries between the p body areas 33 and the n drift area 30 are formed in an inclined shape instead of a stepwise shape. Therefore, electric field concentration can be further relaxed, and the reliability can be enhanced.

### Modified Example 2

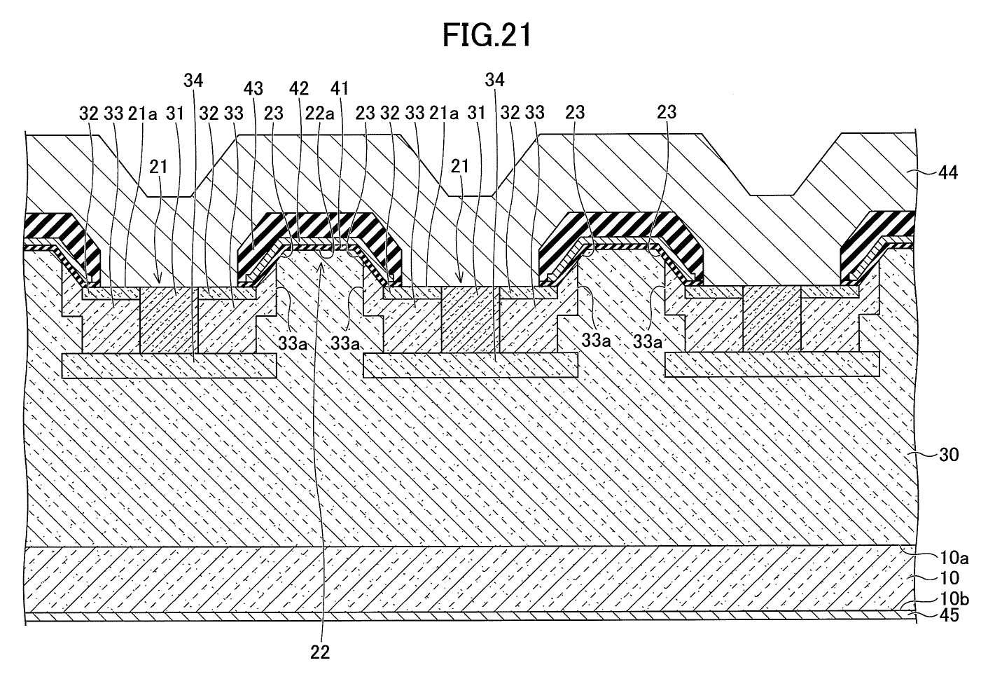

Also, a semiconductor device according to the present embodiment may have a structure as illustrated in FIG. 21 in which p areas 34 are formed at positions deeper than the p⁺ contact areas 31 and the p body areas 33. The p areas 34, the p⁺ contact areas 31, and the p body areas 33 are in contact at the deepest positions of the p⁺ contact areas 31 and the p body areas 33. In this semiconductor device, the concentration of the impurity element for p-type is preferably such that the p⁺ contact areas 31<the p areas 34<the p body areas 33. By forming such p areas 34, according to the present embodiment, resistance in the forward direction of a built-in diode (body diode) formed together with a transistor can be decreased. Note that the p areas 34 may be formed by ion-implanting an impurity element for p-type, and when forming the silicon carbide epitaxial layer 20 on the one main surface 10a of the single-crystal silicon carbide substrate 10, the p areas 34 may be formed during epitaxial growth.

According to the present disclosure, it is possible to provide a semiconductor device using silicon carbide having high channel mobility and low on-resistance.

The embodiment disclosed above is an example in all respects and should be considered to be not restrictive. The scope of the present invention is defined not by the description above but by claims and is intended to include meanings equivalent to the claims and all modifications within the scope.

### Description of the Reference Numerals

10 single-crystal silicon carbide substrate
10a one main surface
10b the other main surface
20 silicon carbide epitaxial layer
20a surface
21 recessed portion
21a bottom surface
22 protruding portion
22a upper surface
23 inclined surface
23b boundary between the inclined surface and the protruding portion
30 n drift area
31 p⁺ contact area
32 n⁺ contact area
33 p Body area
33a boundary
41 gate insulating film
42 gate electrode
43 interlayer insulating film
44 source electrode
45 drain electrode

1. A semiconductor device comprising:
a single-crystal silicon carbide substrate;
a silicon carbide epitaxial layer formed on one main surface of the single-crystal silicon carbide substrate;
a recessed portion and a protruding portion formed on a surface of the silicon carbide epitaxial layer and an inclined surface formed between the recessed portion and the protruding portion;
a first contact area of first conductivity type formed on the inclined surface side of a bottom surface of the recessed portion;
a second contact area of second conductivity type in contact with the first contact area at the bottom surface of the recessed portion;
a drift area of first conductivity type formed on an upper surface of the protruding portion;
a body area of second conductivity type formed on the inclined surface between the first contact area and the drift area;
a gate insulating film that covers the inclined surface;
a gate electrode formed on the gate insulating film;
a source electrode formed on the first contact area and the second contact area; and
a drain electrode formed on the other main surface of the single-crystal silicon carbide substrate,
wherein an angle of the inclined surface with respect to the one main surface of the single-crystal silicon carbide substrate is 40° or more and 70° or less.

2. The semiconductor device according to claim 1,
wherein a boundary between the drift area and the body area is located at the inclined surface, and
wherein the boundary is vertical to the one main surface of the single-crystal silicon carbide substrate.

3. The semiconductor device according to claim 1, wherein an impurity concentration in the body area is 1×10¹⁷ cm⁻³ or more and 3×10¹⁹ cm⁻³ or less.

4. The semiconductor device according to claim 1, wherein at a position deeper than the second contact area and the body area in the silicon carbide epitaxial layer, a semiconductor area of second conductivity type having a higher impurity concentration than in the body area is formed in contact with the second contact area and the body area.

5. The semiconductor device according to claim 1, wherein a planar shape of the recessed portion is a hexagon.

6. The semiconductor device according to claim 1,
wherein the single-crystal silicon carbide substrate has a 4H type crystal structure, and
wherein the silicon carbide epitaxial layer has a 4H type crystal structure.

7. A semiconductor device comprising:
a single-crystal silicon carbide substrate having a 4H type crystal structure;
a silicon carbide epitaxial layer having a 4H type crystal structure and formed on one main surface of the single-crystal silicon carbide substrate;
a recessed portion and a protruding portion formed on a surface of the silicon carbide epitaxial layer and an inclined surface formed between the recessed portion and the protruding portion;
a first contact area of first conductivity type formed on the inclined surface side of a bottom surface of the recessed portion;
a second contact area of second conductivity type in contact with the first contact area at the bottom surface of the recessed portion;
a drift area of first conductivity type formed on an upper surface of the protruding portion;
a body area of second conductivity type formed on the inclined surface between the first contact area and the drift area;
a gate insulating film that covers the inclined surface;
a gate electrode formed on the gate insulating film;
a source electrode formed on the first contact area and the second contact area; and
a drain electrode formed on the other main surface of the single-crystal silicon carbide substrate,
wherein an angle of the inclined surface with respect to the one main surface of the single-crystal silicon carbide substrate is 40° or more and 70° or less,
wherein a boundary between the drift area and the body area is located at the inclined surface,
wherein the boundary is vertical to the one main surface of the single-crystal silicon carbide substrate, and
wherein an impurity concentration in the body area is 1×10¹⁷ cm⁻³ or more and 3×10¹⁹ cm ⁻³ or less.
